(19) United States
(12) Patent Application Publication
(10) Pub. No.: US 2016/0036437 A1
(43) Pub. Date: Feb. 4, 2016

(54) MULTIFUNCTIONAL SWITCH

(71) Applicant: OECHSLER AKTIENGESELLSCHAFT, Ansbach (DE)

(72) Inventors: Winfried SCHMIDT, Wassertruedingen (DE); Matthias WEISSKOPF, Bechhofen (DE); Robert MEIERLE, Stopfenheim (DE)

(73) Assignee: OECHSLER AKTIENGESELLSCHAFT, Ansbach (DE)

(21) Appl. No.: 14/797,339

(22) Filed: Jul. 13, 2015

(30) Foreign Application Priority Data
Aug. 4, 2014 (DE) 10 2014 011 686.7

(51) Int. Cl. H03K 17/96; F21V 8/00

(52) U.S. Cl. CPC H03K 17/962; G02B 6/0095; G02B 6/0065; H03K 2217/960755; H03K 2217/96079

(57) ABSTRACT

In the case of a multifunctional switch (11) with a panel (14), of injection-moulded ceramic for example, coaxially surrounded by a frame (18), the panel (14) and the frame (18) are produced as separate components, which however are connected to one another in a material-bonding and/or form-fitting manner to form one part by means of an annular light guide (20) that particularly radiates axially parallel and is created by material being injected, introduced by flooding or poured into a gap (17) located between them or is adhesively cemented therein.

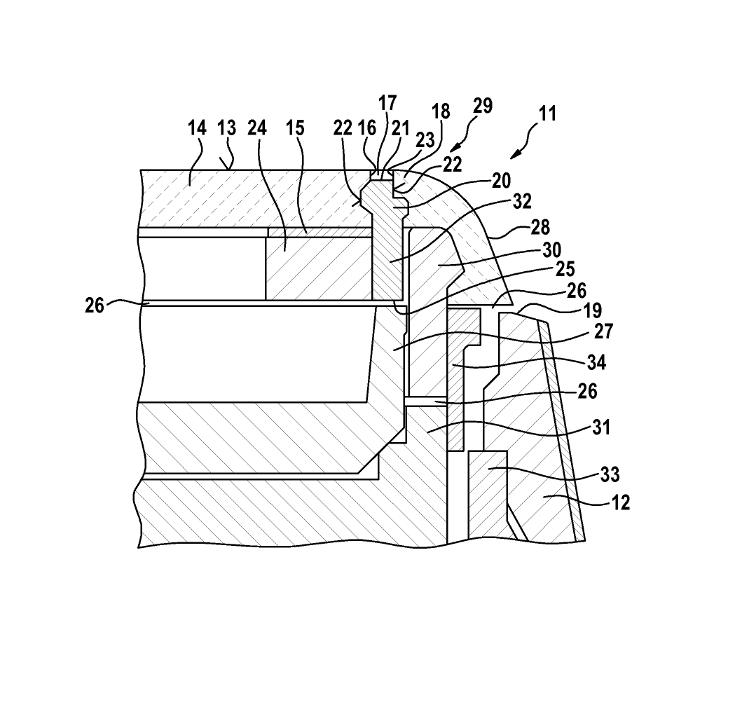

### CROSS-REFERENCE TO PRIORITY APPLICATION

The present application claims priority under 35 U.S.C. §119 to DE 10 2014 011 686.7 filed Aug. 4, 2014, the entire content of which is incorporated herein by reference.

### BACKGROUND DISCUSSION

DE 10 2012 001 073 A1 discloses a capacitive multifunctional switch, which responds location-selectively, and under some circumstances even direction-selectively, to the movement of a fingertip over an injection-moulded ceramic panel, which as a dielectric is backed with electrode sectors connected to an evaluation circuit. For user prompting, dedicated areas of this panel may be marked by means of a light guide, which for this purpose locally transilluminates or protrudes through the panel. Through a tapered annular region designed as a peripheral broad root with chamfer, the border of the panel merges integrally with a frame running around peripherally in the form of a bead. Away from the actuating side (that is to say on the rear side), the latter reaches axially into a hollow-cylindrical supporting structure, which is covered over on the visible side by the frame and the surrounding region of which is designed as an adjusting ring.

Such a ceramic proximity switch has already proven successful in practice; not least in automotive use on account of its outstanding haptics and as a visually high-grade component of a complex operator control unit.

### SUMMARY

The present invention addresses the technical problem of further developing such a multifunctional switch—without being functionally restricted to a proximity sensor—in such a way that on the one hand it is more variable in terms of design and easier in terms of production and on the other hand is nevertheless of a more attractive design and, as a result, with a versatile switch function, as far as possible is also of a more user-friendly design.

This object is achieved according to the invention by the combination of essential features specified in the main claim.

Accordingly, the switch is made up of a panel and a frame surrounding the latter. These can be produced in a multipart form—no longer necessarily from injection-moulded ceramic—much less problematically by injection moulding than the previously known integral component with the comparatively thin dielectric panel and its surrounding accumulation of material, moulded over an annular region that is particularly at risk of breaking since it is weakened, to form the conversely thick bead in the form of a frame. Instead of being formed from injection-moulded material, the panel and/or the frame may, however, also be formed from natural materials or even from metal, in particular from lightweight metal. The components, the panel and its frame, are now connected to one another to form a manageable part by way of a thin-walled, in principle annular, light guide. As a slender, attractive illuminated ring, it emits light on the visible side substantially axially parallel along the border of the planar, convex or locally structured, but not necessarily circular, surface of the panel. This light-guiding connecting “ring” does not necessarily have to follow an uninterrupted peripheral path here, but may also radiate discontinuously, that is to say sectorially divided, screened or with different degrees of intensity or colour, for instance for the optical marking of sectors of the panel, and consequently operating sectors, that are delimited from one another; especially if it is intended that the panel of the multifunctional switch together with its frame should not only be manually displaced axially, but also, according to a development of the invention, tilted into a defined sloping position by introducing a force off-centre.

In this description of the invention, therefore, the concept of the light-emitting light-guide ring is used throughout, even when it is not circular in cross section or when its emission does not follow a continuous peripheral path, because its face is covered or interrupted in certain regions, or when the ring is of a multipart form, for instance has individual axially parallel rods or radial bars with common or individual irradiation. What is decisive is the—continuous or discontinuous—trace of light along the transition of any geometrical design from the central panel to the surrounding frame.

Since the frame is now no longer an integral part of the panel, the panel and the frame no longer have to consist of the same material, but instead may be formed individually, in the case of injection-moulded materials including by multi-component injection moulding. Separate injection moulding, even of completely different injection-moulding materials, opens up interesting possibilities (because of the freedom they offer) for practical needs, in terms of introducing light-emitting and/or later haptically acting symbols as inserts into the moulds for the panel and/or for the frame. On the other hand, the panel and the frame can now be formed independently of one another, both with largely any degree of complexity, in particular the panel as non-circular or with a structured surface and the frame in the manner of a deep-drawn, bell-shaped peripheral ring shroud for the axial concealment on the visible side of structural parts that are situated behind in the lower part of the switch.

According to requirements, transparent to translucent plastic, including plastic that is coloured completely or in certain regions, can be used for the production of a light guide as a luminous connecting ring by means of which the panel and the frame can be connected to one another to form one part. In this way, the panel and the frame are connected to one another at least in a material-bonding or form-fitting manner to form a module. In particular, it is possible to introduce the material for the annular light guide between the panel and the frame in multi-component injection moulding in a visually differing manner, for instance for different peripheral regions. This is of particular interest in technical terms of production if the panel and the frame are produced in the same injection mould. Depending on the materials to be connected to one another and their consistency, the material of the light guide may however also be introduced in a separate operation into the gap between the panel and the frame from a separate production process, to be specific by being injected under pressure or poured in virtually without pressure, or even just introduced by flooding; a particularly broad range of plastics are available for the pressureless variant, which allows better adaptation to the material properties of the panel and the frame. Or the light-guide ring is moulded separately, and is then mounted as a profiled holder between the panel and the frame. If it is intended that this light ring is instead or additionally to be adhesively cemented between the outer surrounding surface of the panel and the inner surrounding surface of the frame, its light-emitting surfaces must as far as possible be unwetted; or an adhesive that still conducts light after its curing is used.

On the other hand, depending on the geometrical and material-typical conditions, it may also be expedient in the case of production by plastics injection moulding not to connect the two components, the panel and the frame, right away to the light guide on both sides thereof in the injection moulding to form one part with it, but instead to restrict operations initially to one side thereof and then connect the component on the opposite side at a later time by a mounting technique.

It is primarily intended that the light guide should radiate axially parallel in the slender bordering region of the radial transition from the panel to the frame. For this purpose, its face may finish flush with the surface of the panel and the frame, or end set back therefrom. It may however also be provided, possibly additionally, to make the light guide radiate all around or locally into the panel and/or into the frame by way of radial coupling-out surfaces when or where the materials of the panel and/or frame are for their part light-conducting. If there are gaps in the annular path of the light guide (or over the course of it), the frame can then radiate centripetally towards the border of the panel and into the latter. In particular wherever the irradiated frame protrudes axially beyond the level of the panel, light can be coupled out at the inner surrounding surface thereof and then radiates centripetally at a shallow irradiating angle over the panel and, in addition to illuminating the surface of the panel, visually highlights haptic profiles mounted or formed on it by interactions of light and shadow.

The multifunctional switch according to the invention is enhanced in its haptic and visual quality if at least the panel and/or at least the frame is/are formed from injection-moulded ceramic. Because of the particularly thermally differing behaviour of ceramic on the one hand and the light-conducting material of the connecting ring on the other hand, a purely material-bonding connection of the ceramic components is then preferably not formed by way of the light guide. According to an additional development of the solution according to the invention, instead the mutually contacting surfaces in the gap between the panel and the frame are profiled in such a way that the light-conducting material injected between them in any event also has the effect of producing form-fitting connections of the panel to the frame by way of the light-guide ring. Such formations may at the same time be designed for promoting the mentioned coupling-out of the light radially into the panel or into the frame, where these likewise comprise light-conducting (transparent or at least translucent) material, at least in certain regions.

In addition, it is generally advantageous, because of differing shrinkage behaviour between unlike material pairings, to form at least on their surfaces small engaging structures that by their form fits prevent unwanted coaxial turning of components with respect to one another.

Further alternatives and additional developments of the invention are provided by the further claims and, also considering their advantages, by the description that follows of a preferred exemplary embodiment of the solution according to the invention that is schematically depicted approximately to scale and reduced to the functional essentials. The single FIGURE of the drawing shows in a broken-away axial section the structure and installation of visual components and operating components, ceramic in the case of this example, of a capacitive, possibly selective, multifunctional switch.

### BRIEF DESCRIPTION OF THE DRAWINGS

The sole FIGURE is a side cross-sectional view of a multifunctional switch according to an embodiment of the present application.

### DETAILED DESCRIPTION

The schematically depicted switch 11 can be operated by a person with their fingertips, by turning a surrounding surface, designed as an adjusting ring 12, of a lower part 31 of the switch, preferably produced by plastics injection moulding, about its axis (outside the diagram); by exerting axial pressure on the surface 13 of a panel 14, which can be slightly moved axially or possibly also tilted; and by passing a hand over the surface 13, either in close proximity or in contact therewith, of the panel 14, which as a dielectric is arranged over electrodes 15 that are preferably segmented.

As a result of a gap 17, running peripherally along its, circular or non-circular, border 16, the panel 14 is surrounded at a centrifugal distance by a frame 18. In the schematically depicted exemplary embodiment, the frame extends in the manner of a bell in longitudinal section in the direction of the adjusting ring 12, the peripheral front edge 19 of which lies axially behind and radially outside the frame 18 in the viewing direction.

The annular gap 17 along the border 16 of the panel, which follows any desired path, is provided over at least a partial region of its axial height, annularly all around or discontinuously, with at least one substantially axially parallel extending and radiating light guide 20. The light guide radiates with its face 21 on the visible and operating side, possibly as depicted axially set back with respect to the surfaces of the panel 14 and/or of the frame 18, as a slender light ring—continuously all around or discontinuously segmented. This helps to locate the operating surface 13 of the panel 14 in dark surroundings; and that makes it possible, in the given case of the example of a dielectric panel 14, to present a sectorial division and delimitation of the underlying electrodes 15 with respect to one another; or to distinguish sectorially differing functions from one another, for instance by the intensity or colouration of the light ring.

However, the light guide 20 serves especially for the mechanical connection between the panel 14 and the frame 18 of the switch 11 to form a part that is manageable in technical terms of assembly. As already mentioned above, in a correspondingly equipped injection mould (not represented in the drawing), the light guide 20 may for this purpose be created by material being injected into the gap 17 between the panel 14, produced by injection moulding, and the frame 18, produced by injection moulding, at an appropriately great pressure according to the material of the light guide to be used, poured in at low pressure or even introduced by flooding virtually without pressure; or a light guide 20 produced separately by injection moulding is mounted between the separately produced components that are the panel 14 and the frame 18 in a force-fitting, form-fitting and/or material-bonding manner.

In the interests of an (also) form-fitting mechanical connection of the light guide 20 to the border 16 of the panel 14 on the one hand and to the inner surrounding surface 23 of the frame 18 on the other hand, the adjoining surrounding surfaces 22 of the, typically largely hollow-cylindrical, light guide 20 are profiled; as indicated by the schematically depicted tongue-and-groove-like radial engagements on both sides, running around continuously or discontinuously, on both sides of the light guide 20 radially thickened for this purpose.

Underneath the gap 17, the light guide 20 also extends with a hollow-cylindrical sleeve 32 over at least part of the axial height of a circuit block 24. The circuit block is designed for instance for the evaluation of operation-dependent variations in local capacitance. The electrodes 15, segmented for this purpose, are arranged, preferably adhesively cemented, between the dielectric panel 14 and the circuit block 24.

The light guide 20 ends with at least a partial region of its rear face 25 at a slight axial distance 26 from a preferably likewise injection-moulded feeding guide 27, into which a light source (outside the drawing) radiates inside the switch 11. In order to avoid as far as possible radiation attenuation at the transition from the feeding light guide 27 to the connecting-ring light guide 20, the distance 26 may be bridged here by light-conducting adhesive. The adhesive is preferably still elastically or plastically deformable even after its curing.

Such an axial distance 26 is also provided between the lower end of the outer border 28 of the frame 18 and the axially opposite front edge 19 of the adjusting ring 12 in order, as already mentioned, to be able to displace axially, or laterally tilt in a defined manner, the switch shroud 29 comprising the panel 14 and the frame 16 connected thereto by way of the light guide 20 slightly, but sufficiently to initiate switching functions in the circuit block 24, by manual exertion of a force centrally or eccentrically, counter to a restoring force (not represented).

For mounting this shroud 29 on the switch 11 there is incidentally mounted in the bell-shaped interior of the frame 18 a hollow-cylindrical holder 30, which engages coaxially in the lower part 31 of the switch (not represented), radially outside the feeding guide 27. The lower part is provided rotatably with a hollow-cylindrical support for the adjusting ring 12. Axially offset with respect thereto, an elastic sleeve 34 has been drawn onto the holder 30, in order to avoid noises occurring between the frame 18 and the switch 11. If this sleeve 34 is designed or equipped to be electrically conducting, it acts at the same time in an electrically shielding manner with respect to any external interfering influences on the circuit block 24.

This multifunctional switch 11, described by way of example on the basis of the drawing, with its bell-like shroud 29, is upgraded visually and haptically if, as schematically depicted by the shading, both the panel 14 and the frame 18 (or at least one of these two components) consist(s) of ceramic, in particular of injection-moulded ceramic. In the case of a ceramic panel 14, it can at the same time serve as the dielectric by way of segmented electrodes 15 of a selectively operable capacitive switch 11.

Also in the case of such a design as a capacitive multifunctional switch 11, the panel 14 of injection-moulded ceramic and the frame 18, coaxially surrounding the panel and preferably likewise produced from injection-moulded ceramic, are in fact separate components, but are connected to one another in a form-fitting and/or material-bonding manner to form a single part, to be specific by a hollow-cylindrical light guide 20, which is arranged between them, radiates substantially parallel to the central axis of the switch 11 and, when viewed face-on, appears as a luminous connecting ring.

### LIST OF DESIGNATIONS

11 Switch

12 Adjusting ring

13 Surface (of 14)

14 Panel

15 Electrodes (under 14)

16 Border (of 14)

17 Gap (between 16 and 23)

18 Frame (around 14)

19 Front edge (of 12)

20 Light guide (in 17)

21 Face (on radiating side) (of 20)

22 Surrounding surfaces (of 20)

23 Inner surrounding surface (of 18)

24 Circuit block (with 15 under 14)

25 Face (on rear) (of 20)

26 Distance (between 25 and 27)

27 Feeding guide (outside 24 behind 20)

28 Outer border (of 18)

29 Shroud (comprising 14 and 18)

30 Holder (under 29 in 28)

31 Lower part (of 11, with 12 and 27)

32 Sleeve (of 20 between 17 and 25)

33 Support (for 12)

34 Sleeve (on 30)

1. Multifunctional switch with a panel, surrounded by a frame, and with at least one substantially axially radiating light guide, the panel and the frame, surrounding the panel at a centrifugal distance, being separate components which are connected to one another by means of the light guide as a luminous connecting ring that radiates on the visible side as a transition from the panel to the frame.

2. Switch according to claim 1, wherein the light guide is connected in a form-fitting and/or material-bonding manner on the one hand to the panel and on the other hand to the frame.

3. Switch according to claim 2, wherein the light guide is created by material being injected, poured or introduced by flooding into a gap between the panel and the frame, or is adhesively cemented therein.

4. Switch according to claim 1, wherein the light guide runs around between the panel and the frame continuously or discontinuously.

5. Switch according to claim 4, wherein the light guide is designed for annular radiation of a light with changing intensity or colour.

6. Switch according to claim 1, wherein an axial distance between the rear face of the light guide and a feeding guide is bridged by light-conductive material.

7. Switch according to claim 1, wherein the light guide also radiates radially into a panel and/or into a frame.

8. Switch according to claim 7, wherein the frame radiates towards the panel.

9. Switch according to claim 8, wherein the frame radiates over a panel with a profiled surface.

10. Switch according to claim 1, wherein the frame reaches axially in the manner of a bell over a lower part of the switch provided with an adjusting ring.

11. Switch according to claim 1, wherein a circuit block loaded with electrodes is arranged under a panel of injection-moulded ceramic, radially within a sleeve-like extension of the light guide located under the gap.
